(19) United States
(12) Patent Application Publication
(10) Pub. No.: US 2005/0270873 A1
(43) Pub. Date: Dec. 8, 2005

(54) IMPULSE DRIVING APPARATUS AND METHOD FOR LIQUID CRYSTAL DEVICE

(76) Inventors: Ssu-Ming Lee, Taipei County (TW); Seob Shin, Taoyuan (TW); Feng-Ting Pai, Hsinchu City (TW); Hsien-Wen Chou, Taoyuan County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/907,741

(22) Filed: Apr. 14, 2005

(30) Foreign Application Priority Data
Jun. 7, 2004 (TW) 93116297

(51) Int. Cl. G11C 7/00

(52) U.S. Cl. 365/205

(57) ABSTRACT

An impulse driving method and apparatus for liquid crystal device are provided. A data driver of the LCD outputs pixel data signals for driving pixels of the LCD at a first level of the load signal. Next, the data driver outputs black data signals for driving pixels of the LCD at a second level of the load signal. Thus, the image dragging problem is resolved by using the impulse driving method and apparatus according to an embodiment of the present invention, and the need of double frequency for the load signal is prevented.

### CROSS-REFERENCE TO RELATED APPLICATION

This application claims the priority benefit of Taiwan application serial no. 93116297, filed on Jun. 7, 2004. All disclosure of the Taiwan application is incorporated herein by reference.

### BACKGROUND OF THE INVENTION

1. Field of Invention

The present invention relates to a liquid crystal device. More particularly, the present invention relates to an impulse driving apparatus and method thereof for liquid crystal devices.

2. Description of Related Art

Recently, the cathode ray tube (CRT, herein after) display devices are gradually being replaced by liquid crystal displays. The improvements of semiconductor technology enable liquid crystal displays to deliver many benefits including low power consumption, slim shape, light weight, high resolution, good color saturation, and long product life. Hence liquid crystal displays are widely used in electronic devices, such as display screens of portable computers or desktop computers, televisions (TVs), etc. Wherein, the quality of a liquid crystal device is the key factor for a good quality liquid crystal display.

Referring to FIG. 1, the block diagram of a conventional thin film transistor LCD is shown. Wherein, a data driver 110 drives a plurality of data lines 112˜118 to output data signals for driving pixels, a gate driver 130 drives a plurality of gate lines 132˜138 that are also known as scan lines, and a display area 120 includes a plurality of transistors 152˜168 and storage capacitors 181˜197.

The operation of a conventional liquid crystal display is described as follows. First, a gate line, e.g. gate line 132 is driven for turning on the transistors 152˜156 on the gate line 132. At the same time, pixel data signals for displaying are inputted through data lines 112˜118 to charge storage capacitors 181˜185. Then, the next gate line is driven, e.g. gate line 134, and the pixel data signals for displaying are inputted through data lines 112˜118 to charge storage capacitors 187˜191. Accordingly, storage capacitors 181˜197 in the display area 120 are charged in sequence for displaying a complete image.

The operations described above are perfect for displaying a static image. But an image dragging will occur to the dynamic image with a fast refresh speed while the voltage charged to storage capacitors can not be refreshed in time. In order to resolve the problem of image dragging when displaying dynamic images, the Samsung Electronics of Korea had proposed an impulse driving liquid crystal display by emulating CRT operations according to the Korea patent No. 2002-0066823, which is published on Aug. 21, 2002.

Referring to FIG. 2, an operating timing diagram of the impulse driving liquid crystal display proposed by Samsung Electronics is shown. Wherein, DATA is an image data on data line for driving pixels, STH is a start horizontal signal, TP is a load signal, CPV is a gate clock signal, and STV is a start vertical signal. In order to emulate the impulse display operations of a CRT, the image data DATA is outputted as the pixel data with a black data inserted in 1H cycle of the scan line, as shown in FIG. 2. Then a data driver receives and stores the image data on data lines and generates data signals for driving pixels according to the start horizontal signal STH and the load signal TP. Meanwhile, a gate driver generates scan signals for driving gate lines according to the gate clock signal CPV and the start vertical signal STV.

However, according to the timing diagram in FIG. 2, the aforementioned method requires double frequency for the start horizontal signal STH and the load signal TP compared to the operation of a conventional liquid crystal display and hence limiting the charging time for storage capacitors to only half of the original charging time or even less. Furthermore, additional line memories are required because pixel data and black data are transmitted alternately.

### SUMMARY OF THE INVENTION

Accordingly, the present invention is directed to an impulse driving method for liquid crystal device (LCD, herein after), wherein double frequency signals are not needed so as to improve the aforementioned problems.

The present invention is also directed to an impulse driving apparatus for LCD using only regular frequency signals without additional line memories.

According to an embodiment of the present invention, an impulse driving method for LCD is provided. Wherein a data driver of the LCD outputs data signals to drive pixels of the LCD according to a received load signal. The said impulse driving method for LCD comprises following procedures. At a first level of the load signal, a data driver outputs normal signals for driving pixels of the LCD. Next, at a second level of the load signal, the data driver outputs auxiliary signals for driving pixels of the LCD. According to an embodiment of the present invention, the normal signal is a pixel data signal and the auxiliary signal may be a black data signal or a white data signal.

Furthermore, the voltage level of the aforementioned auxiliary signal may be generated by an internal circuit of the data driver integrated circuit or by an external circuit.

Therefore, the gate driver of the LCD generates scan signals for controlling a plurality of gate lines according to the start vertical signal and gate clock signal. When the data driver outputs normal signals, the gate driver conducts the i^{th} gate line. Next, the data driver outputs auxiliary signals, the gate driver conducts the i+j^{th} gate line to eliminate the pixel data selected by the i+j^{th} gate line. Thus, an impulse driving signal is generated as required. Certainly, besides the i+j^{th} gate line, the gate driver may conduct a i+j+2^{th}, a i+j+4^{th} . . . etc. gate lines concurrently to eliminate the pixel data selected by the i+j+2^{th}, the i+j+4^{th} . . . etc. gate lines. Thus, the required impulse driving signals are generated.

According to another embodiment of the present invention, an impulse driving apparatus for LCD comprises a timing controller, a data driver and a gate driver. Wherein, the timing controller outputs image data and control signals including a load signal, a start vertical signal and a gate clock signal. The data driver is coupled to the timing controller to output pixel data signals for driving the LCD pixels when at a first level of the load signal. The data driver further outputs black data signals for driving the LCD pixels when at the second level of the load signal. The gate driver is coupled to the timing controller to generate scan signals for controlling a plurality of gate lines according to the start vertical signal and gate clock signal. Wherein, a normal signal comprises the said pixel data signal, and an auxiliary signal comprises the said black data signal as well as a white data signal.

Furthermore, the voltage level of the aforementioned auxiliary signal may be generated by an internal circuit of the data driver integrated circuit or by an external circuit.

According to an embodiment of the present invention, when the data driver outputs the pixel data signals, the gate driver conducts the i^{th} gate line. Then the data driver outputs black data signals, the gate driver conducts the i+j^{th} gate line to eliminate the pixel data selected by the i+j^{th} gate line. Thus, the required impulse driving signal is generated.

In another aspect, when the data driver outputs pixel data signals, the gate driver conducts the i^{th} gate line. Then the data driver outputs black data signals, the gate driver conducts the i+j^{th}, the i+j+2^{th}, and the i+j+4^{th} . . . etc. gate lines concurrently to eliminate the pixel data selected by the i+j^{th}, the i+j+2^{th}, and the i+j+4^{th} . . . etc. gate lines. Thus, the required impulse driving signals are generated.

According to an embodiment of the present invention, the first level of the load signal is a low voltage level, while the second level of the load signal is a high voltage level.

The impulse driving method and apparatus for LCD according to an embodiment of the present invention utilizes different voltage levels of the load signal for loading pixel data signals and black data signals. Hence the needs of double frequency for the start horizontal signal and the load signal are prevented, and the charging time of the storage capacitor can keep under control. Furthermore, since the timing controller does not need to transmit the pixel data and the black data to the data driver alternately, and therefore the cost of the system can be effectively reduced as comparatively less quantity of line memories are required.

In order to the make the aforementioned and other objects, features and advantages of the present invention comprehensible, a preferred embodiment accompanied with figures is described in detail below.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic block diagram of a conventional thin film transistor LCD.

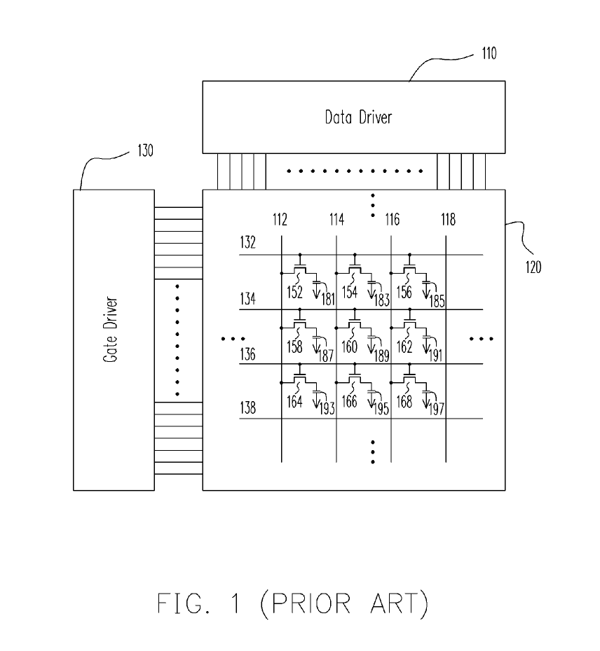

FIG. 2 is a timing diagram of an impulse driving liquid crystal display proposed by Samsung Electronics.

FIG. 3 is a schematic block diagram of an impulse driving apparatus for liquid crystal device according to an embodiment of the present invention.

FIG. 4 is an operating timing diagram of a data driver of an impulse driving apparatus for liquid crystal device according to an embodiment of the present invention.

FIG. 5 is an operating timing diagram of a gate driver of an impulse driving apparatus for liquid crystal device according to an embodiment of the present invention.

### DESCRIPTION OF EMBODIMENTS

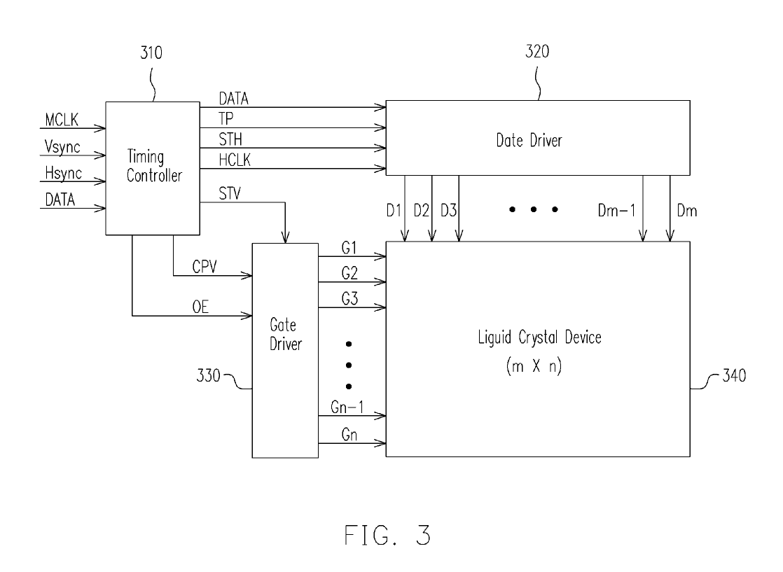

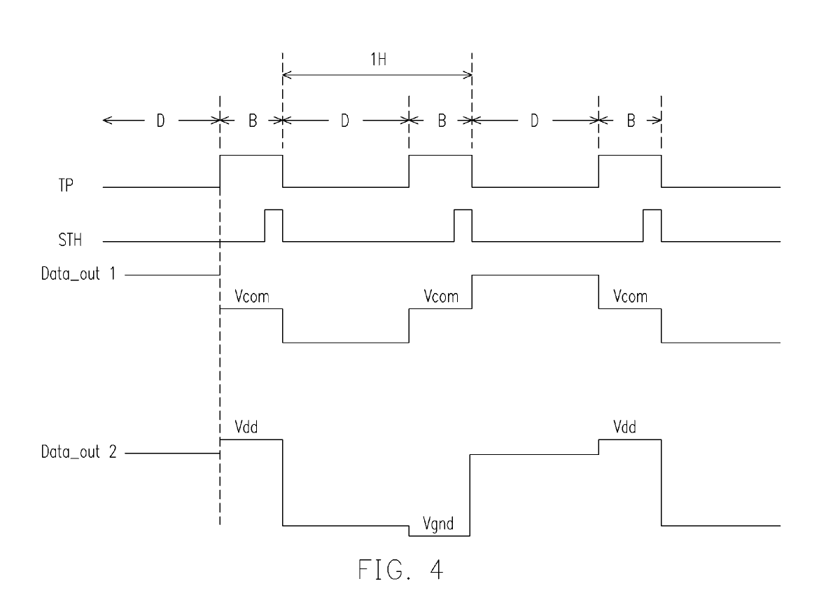

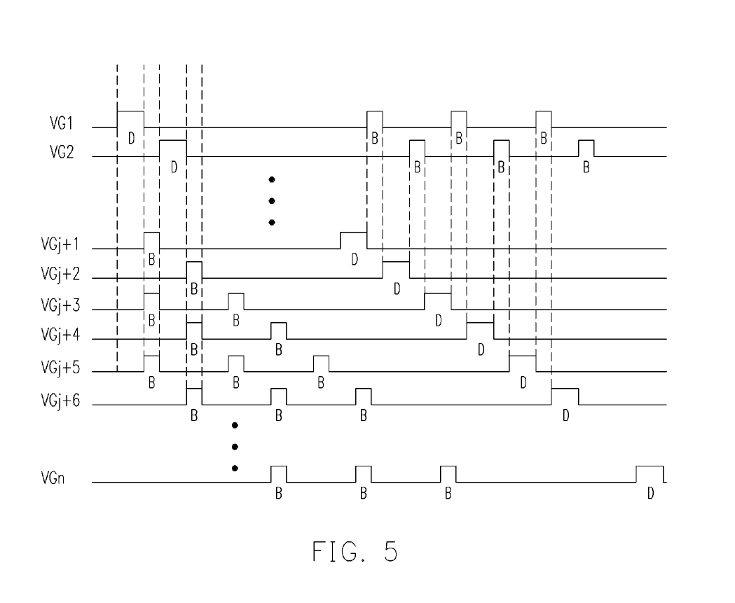

Referring to FIG. 3, a schematic block diagram of an impulse driving apparatus for LCD according to an embodiment of the present invention is shown. As shown in FIG. 3, the apparatus comprises a timing controller 310, a data driver 320 and a gate driver 330, for driving the LCD 340.

Wherein, the timing controller 310 outputs image data DATA and control signals including a load signal TP, a start vertical signal STH, a horizontal clock signal HCLK, a start vertical signal STV, a gate clock signal CPV and an output enable signal OE. According to the aforementioned image data and control signals outputted from the timing controller 310, the data driver 320 and the gate driver 330 generate data signals and scan signals for driving the LCD 340. Accordingly, the data signals are conducted pixels on the correct scan lines for displaying, when the scan signals are sequentially outputted from gate lines G1 till Gn and the data signals are transmitted from data lines D1 till Dm. The detailed operating timing diagrams are shown in FIG. 4 and FIG. 5.

Referring to FIG. 4, an operating timing diagram of the data driver of an impulse driving apparatus for liquid crystal device according to an embodiment of the present invention is shown. Besides the load signal TP and the start horizontal signal STH, the operating timing for the data signal Data_out1 in a normally black LCD and the data signal Data_out2 in a normally white LCD are also shown. Wherein, the data driver 320 receives the image data DATA from the timing controller 310 according to the start horizontal signal STH, as well as outputs normal signals D and auxiliary signals B for driving the LCD 340 according to the voltage level of the load signal TP. The aforementioned normal signals may be the pixel data signals for example, while the auxiliary signals may be black data signals or white data signals. Although the pixel data signals and the black data signals are adopted according to the embodiment of present invention, yet the scope of the present invention is not limited to above descriptions.

The aforementioned pixel data signal D is the gamma voltage value equivalent to the normal data for displaying, while the auxiliary signal B is the gamma voltage value which displays a pixel black or white. Namely, when the LCD is normally black, the auxiliary signal B is the gamma voltage value equivalent to Vcom, as shown by the data signal Data_out1. When the LCD is normally white, the auxiliary signal B is the gamma voltage value equivalent to a high voltage level Vdd or a low voltage level Vgnd, as shown by the data signal Data_out2.

Furthermore, the voltage level of the auxiliary signal, e.g. voltage level of the aforementioned black data signal, may be generated by an internal circuit of the data driver integrated circuit or generated by an external circuit. When the auxiliary signal is generated by an internal circuit of the driver integrated circuit, the voltage level of the auxiliary signal may choose the gamma voltage value of black pixel, e.g. in above descriptions, or Vdd at a positive time frame period (“positive field” hereinafter) and Vgnd at a negative time frame period (“negative field” hereinafter). When the auxiliary signal is generated by an external circuit, the voltage level may have a constant voltage level for a DC (direct current) mode, or different voltage levels at the positive field and the negative field for an AC (alternating current) mode. As known in the art, the DC mode is adaptive to normally black data, however, the AC mode is adaptive to normally white data. Accordingly, another technical feature and accomplishments of the present invention is provided. The voltage level of the aforementioned auxiliary signal may be adjusted facilely, and the root mean square value of the data signal for driving liquid crystal display can be adjusted by changing the voltage level of the auxiliary signal.

Accordingly, the operating timing of the data driver 320 is as follows. When the load signal TP is at the first level, e.g. a low voltage level, the pixel data signal D is outputted for driving the pixel of LCD 340. When the load signal TP is at the second level, e.g. a high voltage level, the black data signal B is outputted for driving the pixel of LCD 340 in order to reset the pixel voltage on the scan line, thereby to generate the impulse driving effect.

In another aspect, a normal cycle D is defined when the load signal is at the first level within a cycle time of the start horizontal signal STH, i.e. within 1H cycle of each scan line. Meanwhile, an auxiliary cycle B is defined when the load signal is at the second level within the cycle time of the start horizontal signal STH. Therefore, the feature of an impulse driving method according to the present invention is as follows. During a normal cycle D, the data driver outputs normal signals, e.g. pixel data signals, for driving the pixels of the LCD 340; during an auxiliary cycle B, the data driver outputs auxiliary signals, e.g. black data signals, for driving the pixels of the LCD 340 to reset the pixel voltage on scan lines, thereby generate the impulse driving effect.

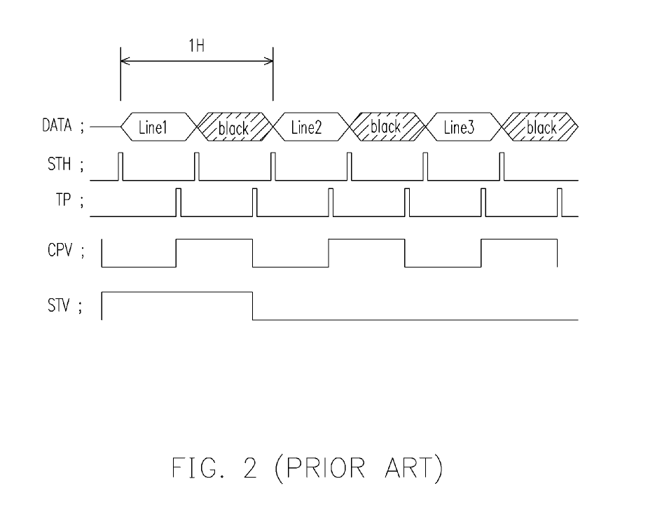

According to the comparison of FIG. 2 and FIG. 4, the present invention provides apparent advantages. The normal signal and the auxiliary signal are loaded respectively within a cycle time of the start horizontal signal STH according to different levels or different states of the load signal TP. Therefore, both the normal signal and the auxiliary signal are driven once respectively within a cycle time of the start horizontal signal STH. On the contrary, two cycle times of the start horizontal signal STH are required to drive the normal signal and the auxiliary signal once according to the prior art. Hence, the present invention is advantageous compared to prior art since double frequency for the start horizontal signal and the load signal are not needed. Furthermore, the black data signal output can be controlled by the duration of the load signal TP at second level according to the present invention; that means, the duration of the load signal TP at the second level depends on the charging time required by the liquid crystal characteristics, which is unlimited. Hence, the duration of the load signal TP according to the present invention can be longer compared the duration of the load signal TP according to the prior art, as shown in FIG. 2.

Referring to FIG. 5, an operating timing diagram for the gate driver of an impulse driving apparatus for LCD according to an embodiment of the present invention is shown. The operating timing of gate lines VG1˜VGn is also shown in FIG. 5, where the D stands for the duration of pixel data signals D outputted from the data driver 320 in FIG. 4. While the B stands for the duration of black data signals B outputted from the data driver 320 in FIG. 4, which means the duration of inserting black data.

According to FIG. 5, the gate driver 330 sequentially outputs scan signals to drive each gate line. In addition, the gate driver generates a black inserting scan signal after a normal scan signal to reset pixels, so as to perform the effect of impulse driving. According to an example of the operating timing shown in FIG. 5, the data driver 320 outputs pixel data signals D and gate driver 330 conducts the i^{th} gate line. Then the data driver 320 outputs black data signals B, the gate driver 330 conducts the i+j^{th}, the i+j+2^{th}, and the i+j+4^{th} . . . etc. gate lines concurrently to eliminate the pixel data selected by the i+j^{th}, the i+j+2^{th}, and the i+j+4^{th} . . . etc. gate lines. Thus, the required impulse driving signals are being generated. For example, the timing for driving VGj+1, VGj+3, and VGj+5 . . . etc. are generated immediately after the VG1 is driven, as shown in FIG. 5. Wherein, the value of j may be one half of total gate line number or any other chosen value. Surely, A person of ordinary skill in the art will understand that above descriptions present only a typical embodiment of the present invention and not the only embodiment of the present invention.

Accordingly, an impulse driving method for LCD is concluded. The data driver of the said LCD outputs data signals to drive pixels of LCD according to the load signal received. Hence, the impulse driving method for LCD comprises at the first level of the load signal, the data driver outputs pixel data signals for driving pixels of the LCD and at the second level of the load signal, the data driver outputs black data signals for driving pixels of the LCD.

Wherein, the gate driver of the LCD generates scan signals for controlling a plurality of gate lines according to the start vertical signal and gate clock signal. When the data driver outputs pixel data signals, the gate driver conducts the i^{th} gate line. Then the data driver outputs black data signals, the gate driver conducts the i+j^{th} gate line to eliminate the pixel data selected by the i+j^{th} gate line, hence the required impulse driving signal is generated. Alternatively, the gate driver may conduct the i+j+2^{th}, the i+j+4^{th} . . . etc. gate lines concurrently besides the i+j^{th} gate line, in order to eliminate the pixel data selected by the i+j+2^{th}, the i+j+4^{th} . . . etc. gate lines. Thus, the required impulse driving signals are being generated.

Wherein, the value of j may be one half of total gate line number or any other chosen value. While the aforementioned first level may be a low voltage level and the second level may be a high voltage level.

Accordingly, the present invention describes an impulse driving method and apparatus for LCD with reference to FIG. 4 and FIG. 5. Wherein, a cycle time of start horizontal signal is divided into a normal cycle and a complementary cycle according to the different states of the load signal, whereby the normal signals and the auxiliary signals are loaded accordingly. Accordingly, double frequency for the start horizontal signal and the load signal can be effectively avoided, and the charge time for the storage capacitor can be kept under control. Furthermore, since the timing controller need not transmit the pixel data and the black data to the data driver alternately, and therefore requires comparatively lesser quantity of line memories and thereby reducing the overall cost of the system.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. An impulse driving method for a liquid crystal device (LCD), the LCD comprising a plurality of pixels and a data driver for driving pixels, the impulse driving method comprising:
outputting a normal signal for driving the pixels according to a load signal, wherein the load signal is at a first level and the normal signal is outputted by the data driver; and
outputting an auxiliary signal for driving the pixels, wherein the load signal is at a second level and the auxiliary signal is outputted by the data driver.

2. The impulse driving method as recited in claim 1, wherein the normal signal is a pixel data signal and the auxiliary signal is a black data signal or a white data signal.

3. The impulse driving method as recited in claim 1, wherein a voltage level of the auxiliary signal is generated by an internal circuit of the data driver integrated circuit.

4. The impulse driving method as recited in claim 3, wherein the voltage level of the auxiliary signal has a low voltage level at a positive time frame period and a high voltage level at a negative time frame period.

5. The impulse driving method as recited in claim 3, wherein the voltage level of the auxiliary signal is a gamma voltage value of black or a gamma voltage value of white.

6. The impulse driving method as recited in claim 1, wherein a voltage level of the auxiliary signal is generated by an external circuit of the data driver integrated circuit.

7. The impulse driving method as recited in claim 6, wherein the voltage level of the auxiliary signal on a DC mode has a constant voltage level at a positive time frame period and at a negative time frame period.

8. The impulse driving method as recited in claim 6, wherein the voltage level of the auxiliary signal on an AC mode has different voltages levels at a positive time frame period and a negative time frame period.

9. The impulse driving method as recited in claim 1, wherein the LCD comprises a gate driver for generating scan signals for controlling a plurality of gate lines according to a start vertical signal and a gate clock signal.

10. The impulse driving method as recited in claim 9, wherein when the data driver outputs the normal signal, the gate driver conducts an i^{th} gate line, and when the data driver outputs the auxiliary signal, the gate driver conducts at least an i+j^{th} gate line.

11. The impulse driving method as recited in claim 1, wherein the first level is a low voltage level and the second level is a high voltage level.

12. An impulse driving method for liquid crystal device (LCD), the LCD comprising a plurality of pixels and a data driver for receiving a load signal and a start horizontal signal, the said impulse driving method comprises:
outputting a normal signal for driving the pixels during a normal cycle, wherein the normal signal is outputted by the data driver and the normal cycle is defined as the load signal at a first level within a cycle time of the start horizontal signal; and
outputting an auxiliary signal for driving the pixels during an auxiliary cycle, wherein the auxiliary signal is outputted by the data driver and the auxiliary cycle is defined as the load signal at a second level within the cycle time of the said start horizontal signal.

13. The impulse driving method as recited in claim 12, wherein the normal signal is a pixel data signal and the auxiliary signal is a black data signal or a white data signal.

14. The impulse driving method as recited in claim 12, wherein a voltage level of the auxiliary signal is generated by an internal circuit of the data driver or an external circuit of the data driver.

15. An impulse driving apparatus for LCD, comprising:
a timing controller, for outputting an image signal and a control signal including a load signal, a start vertical signal and a gate clock signal;
a data driver, coupled to the said timing controller, for outputting a normal signal to drive pixels of the LCD at a first level of the load signal and outputting an auxiliary signal to drive the pixels of the LCD at a second level of the load signal; and
a gate driver, coupled to the timing controller, for generating a plurality of scan signals to control a plurality of gate lines according to the start vertical signal and the gate clock signal.

16. The impulse driving apparatus as recited in claim 15, wherein the normal signal is a pixel data signal and the auxiliary signal is a black data signal or a white data signal.

17. The impulse driving apparatus as recited in claim 15, wherein a voltage level of the auxiliary signal is generated by an internal circuit of the data driver or an external circuit of the data driver.

18. The impulse driving apparatus as recited in claim 17, wherein when the data driver outputs the said normal signal, the gate driver conducts an i^{th} gate line, and when the data driver outputs the auxiliary signal, the gate driver conducts at least an i+j^{th} gate line.

19. The impulse driving apparatus as recited in claim 15, wherein the first level is a low voltage level and the second level is a high voltage level.
